(19) United States
(12) Patent Application Publication
(10) Pub. No.: US 2026/0366935 A1
(43) Pub. Date: Nov. 19, 2026

(54) CABLED SENSOR WAFER FOR FLAT BONDING APPLICATIONS

(71) Applicant: KLA Corporation, Milpitas, CA (US)

(72) Inventor: Farhat A. Quli, Castro Valley, CA (US)

(21) Appl. No.: 19/674,941

(22) Filed: May 12, 2026

Related U.S. Application Data
(60) Provisional application No. 63/807,918, filed on May 19, 2025.

(51) Int. Cl. G01L 5/00; G01K 1/022; G01K 1/14; H10P 72/00; H10P 72/10

(52) U.S. Cl. CPC G01L 5/008; G01K 1/022; G01K 1/14; H10P 72/0602; H10P 72/0604; H10P 72/10; H10P 72/0428

(57) ABSTRACT

A sensor module may include a cover. The sensor module may include a substrate located opposite the cover, wherein the substrate and the cover are bonded to each other. The sensor module may include a plurality of sensors positioned between the cover and the substrate, wherein the plurality of sensors is coupled to each other by a plurality of interconnects. The sensor module may include a data acquisition subsystem communicatively coupled to the plurality of sensors, wherein the data acquisition subsystem is designed to receive sensor data from the plurality of sensors. The sensor module may include a cable at an edge of the cover and the substrate, wherein the cable is coupled to the data acquisition subsystem and the plurality of interconnects at a convergence point of the plurality of interconnects.

### CROSS-REFERENCE TO RELATED APPLICATION

The present application claims the benefit under 35 U.S.C. § 119(e) of U.S. Provisional Application Ser. No. 63/807,918, filed May 19, 2025, entitled CABLED SENSOR WAFER FOR FLAT BONDING APPLICATIONS, which is incorporated herein by reference in its entirety.

### TECHNICAL FIELD

The present disclosure relates generally to sensor wafers and, more particularly, to sensor wafers used in bonding applications.

### BACKGROUND

In semiconductor processing and wafer-level sensing, various sensor wafer technologies have been developed to monitor environmental and mechanical conditions during manufacturing operations. These sensor wafers are often employed to measure parameters such as temperature, pressure, and vibration within processing tools, enabling improved process control and equipment diagnostics.

Conventional approaches have exhibited certain limitations. For example, one method utilizes a wireless sensor wafer that, while eliminating the need for physical connections, is constrained by its limited thermal tolerance. This restricts its applicability in high-temperature environments commonly encountered in advanced semiconductor processes. In another approach, a sensor wafer is constructed with a non-planar profile, which can interfere with its compatibility in tools that require precise wafer flatness, such as those used in bonding or metrology applications. The lack of flatness can lead to inaccurate measurements or mechanical incompatibility with standard wafer handling systems and wafer processes.

Accordingly, there remains a need for an improved sensor wafer architecture that maintains a monolithically flat profile suitable for high-precision applications, while also supporting robust data acquisition capabilities under elevated thermal and mechanical stress conditions.

### SUMMARY

A sensor module is disclosed in accordance with one or more embodiments of the present disclosure. In embodiments, the sensor module includes a cover. In embodiments, the sensor module includes a substrate located opposite the cover, wherein the substrate and the cover are bonded to each other. In embodiments, the sensor module includes a plurality of sensors positioned between the cover and the substrate, wherein the plurality of sensors is coupled to each other by a plurality of interconnects. In embodiments, the sensor module includes a data acquisition subsystem communicatively coupled to the plurality of sensors, wherein the data acquisition subsystem is designed to receive sensor data from the plurality of sensors. In embodiments, the sensor module includes a cable at an edge of the cover and the substrate, wherein the cable is coupled to the data acquisition subsystem and the plurality of interconnects at a convergence point of the plurality of interconnects.

A system is disclosed in accordance with one or more embodiments of the present disclosure. In embodiments, the system includes one or more processing tools. In embodiments, the system includes a sensor module designed to measure one or more attributes of the one or more processing tools. In embodiments, the sensor module includes a cover. In embodiments, the sensor module includes a substrate located opposite the cover, wherein the substrate and the cover are bonded to each other. In embodiments, the sensor module includes a plurality of sensors positioned between the cover and the substrate, wherein the plurality of sensors is coupled to each other by a plurality of interconnects. In embodiments, the sensor module includes a data acquisition subsystem communicatively coupled to the plurality of sensors, wherein the data acquisition subsystem is designed to receive sensor data from the plurality of sensors. In embodiments, the sensor module includes a cable at an edge of the cover and the substrate, wherein the cable is coupled to the data acquisition subsystem and the plurality of interconnects at a convergence point of the plurality of interconnects.

A method is disclosed, in accordance with one or more embodiments of the present disclosure. In embodiments, the method includes a step of inserting a sensor module into one or more processing tools. In embodiments, the sensor module includes a cover. In embodiments, the sensor module includes a substrate located opposite the cover, wherein the substrate and the cover are bonded to each other. In embodiments, the sensor module includes a plurality of sensors positioned between the cover and the substrate, wherein the plurality of sensors is coupled to each other by a plurality of interconnects. In embodiments, the sensor module includes a data acquisition subsystem communicatively coupled to the plurality of sensors, wherein the data acquisition subsystem is designed to receive sensor data from the plurality of sensors. In embodiments, the sensor module includes a cable at an edge of the cover and the substrate, wherein the cable is coupled to the data acquisition subsystem and the plurality of interconnects at a convergence point of the plurality of interconnects. In embodiments, the method includes a step of measuring one or more attributes of the one or more processing tools with the sensor module to collect the sensor data. In embodiments, the method includes a step of transmitting or processing the sensor data with the data acquisition subsystem.

### BRIEF DESCRIPTION OF THE DRAWINGS

The numerous advantages of the disclosure may be better understood by those skilled in the art by reference to the accompanying figures.

FIG. 1A illustrates a top perspective view of the sensor module, in accordance with one or more embodiments of the present disclosure.

FIG. 1B illustrates a cross-sectional view of a sensor module, in accordance with one or more embodiments of the present disclosure.

FIG. 1C illustrates an exploded view of the sensor module, in accordance with one or more embodiments of the present disclosure.

FIG. 1D illustrates a block diagram of a data acquisition subsystem of the sensor module, in accordance with one or more embodiments of the present disclosure.

FIG. 2 illustrates a block diagram of a system for manufacturing semiconductors incorporating the sensor module, in accordance with one or more embodiments of the present disclosure.

FIG. 3 illustrates a flow diagram of a method for using the sensor module in manufacturing systems, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to sensor modules designed for use in semiconductor manufacturing environments. More specifically, the disclosed sensor module may be designed to monitor environmental and mechanical conditions, such as temperature, pressure, and vibration, within processing tools using an integrated array of sensors embedded between a bonded cover and substrate. The module may feature a monolithic, wafer-like shape that enables compatibility with standard semiconductor handling and processing equipment.

The sensor module may include a flexible cable extending from its edge, which may serve as both a signal conduit and a platform for integrated electronics. A data acquisition subsystem may be mounted on, or coupled to, the cable, enabling local signal processing, wireless communication, and autonomous operation. This architecture may allow the sensor module to operate in high-temperature or high-pressure environments by positioning sensitive electronics outside the most extreme zones, while maintaining a flat, sealed profile suitable for insertion into a wide range of processing tools.

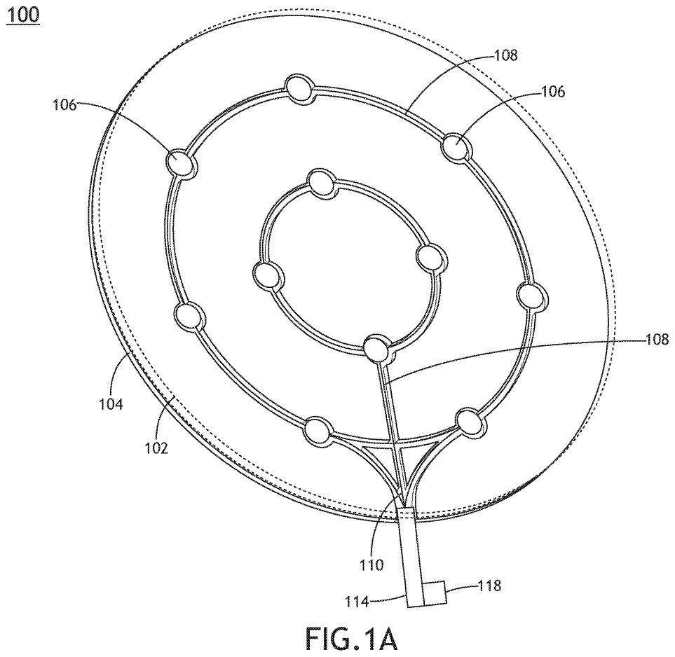

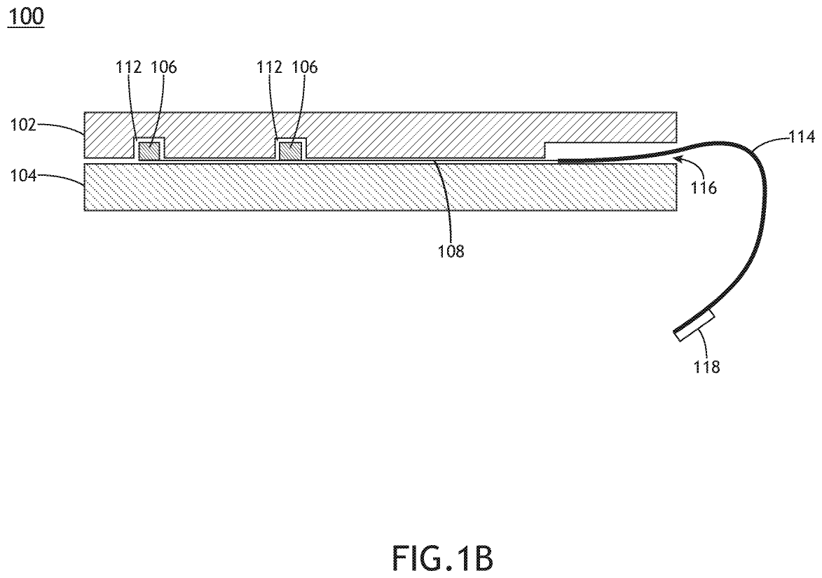

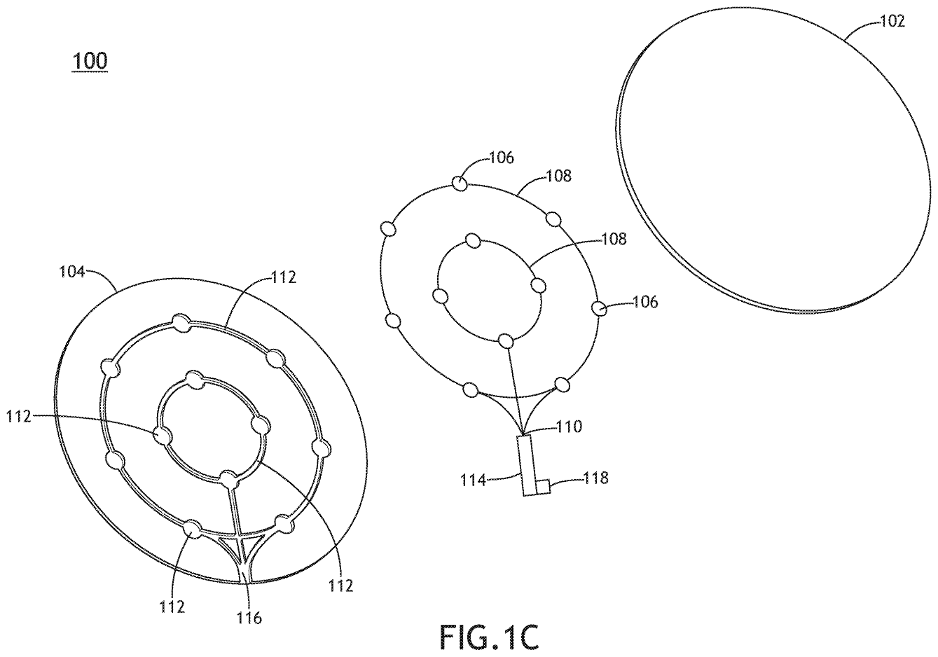

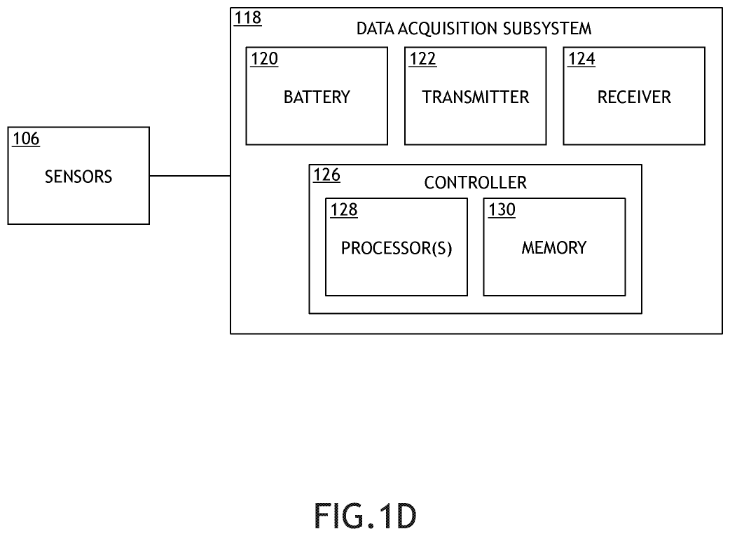

FIGS. 1A-1C illustrate views of a sensor module 100, in accordance with one or more embodiments of the present disclosure. The sensor module 100 may be a monolithically flat assembly (e.g., a wafer-like structure) that may be subjected to significant compressive forces, such as those in a wafer bonding process, without damage to its internal components.

In embodiments, the sensor module 100 includes a cover 102. The cover 102 may include a planar, rigid body (e.g., a semiconductor wafer or a larger panel) made of any suitable material. For example, the cover 102 may be made from materials such as silicon, glass, or ceramic. The cover 102 may be positioned on one side of the sensor module 100 (e.g., forming the top face of the assembly) and may enclose and protect internal components of the module. The cover 102 may provide a flat, continuous exterior surface that may allow the sensor module 100 to mimic a standard wafer or panel and withstand mechanical pressures during use.

In embodiments, the sensor module 100 includes a substrate 104. The substrate 104 may be located opposite the cover 102 (e.g., to form the bottom side of the sensor module 100). The substrate 104 may be bonded to the cover 102 to form the monolithic assembly of the sensor module 100. Like the cover 102, the substrate 104 may be a wafer or panel composed of a suitable material (e.g., silicon, glass, quartz, ceramic, or another rigid substrate).

The substrate 104 may provide structural support for the sensor module 100. The substrate 104 may be bonded to the cover 102 by adhesive bonding, direct bonding, or anodic bonding. For example, the cover 102 and substrate 104 may be bonded with an adhesive layer, where a thin film of high-temperature adhesive may be applied and cured to secure the cover 102 and substrate 104. By way of another example, the cover 102 and substrate 104 may be united by direct bonding (e.g., fusion bonding), where the cover 102 and the substrate 104 may be pressed together and heated to form a bond without any intermediate material. By way of another example, anodic bonding may be employed by applying a high voltage and heat across the interface of the cover 102 and substrate 104 when the substrate 104 and cover 102 are composed of the appropriate materials.

The substrate 104 may be a semiconductor wafer with a diameter corresponding to the cover 102, so that the cover 102 and substrate 104 may align and seal around their periphery when bonded. The bonding between the cover 102 and substrate 104 may be achieved through various techniques resulting in a sealed interior region.

The cover 102 and the substrate 104 may be of various form factors. For example, the cover 102 and substrate 104 may be standard circular wafers (e.g., 200 mm or 300 mm diameter silicon wafers) compatible with conventional wafer handling equipment. By way of another example, the cover 102 and substrate 104 may be larger, substantially flat panels (e.g., square or rectangular panels) used in display manufacturing or advanced packaging processes. The size and shape of the cover 102 and substrate 104 may be selected according to the application, while maintaining a flat, planar profile when bonded together.

In embodiments, the sensor module 100 includes sensors 106. The sensors 106 may be any sensing element appropriate in manufacturing semiconductors. For example, the sensors 106 may be designed to measure temperature, pressure, and/or vibration. By way of another example, the sensors 106 may be thin-film sensors or thick-film sensors. The sensors 106 may be distributed across the substrate 104 (e.g., arranged in an array or radial pattern) to capture spatial variations in the measured parameters. The specific design and type of each sensor 106 may depend on the parameter it is intended to measure and the environmental requirements of the process (e.g., high-temperature stability or high-pressure resistance). All sensors 106 may be positioned such that, when the cover 102 is bonded to the substrate 104, they reside in the sealed gap between the cover 102 and substrate 104.

The sensors 106 may be coupled to one another by interconnects 108. The interconnects 108 may be conductive pathways (e.g., metal traces, flex-circuit lines, or fine wires) that electrically connect the sensors 106 and route their signals to a common output area. The interconnects 108 may be realized as patterned metallization on the substrate 104 (using thin-film deposition and etching or printing of conductive inks), forming a network that links each sensor 106. Alternatively, when discrete sensor components are used, the interconnects 108 may be formed by wire bonds. The network of interconnects 108 may allow multiple sensors 106 to share a communication and power interface without bulky connectors at each sensor 106. In effect, the interconnects 108 may serve as an on-board wiring harness that aggregates the outputs of the distributed sensors 106 and delivers power or signals to the sensors 106 as needed.

The interconnects 108 may all meet at a convergence point 110. The convergence point 110 may refer to a region of the sensor module 100 (e.g., located at or near an edge of the substrate 104) where the interconnects 108 come together or terminate for external access. This configuration means that the outputs (and any inputs) for all sensors 106 may be available at a single location. Such a configuration may simplify the interface between the sensor module 100 and external systems.

The convergence point 110 may be a set of metal pads or a small connector mounted on the substrate 104 at its periphery. By routing all of the interconnects 108 to this area, the sensor module 100 may require only one connection to communicate with external data acquisition electronics, rather than having separate wires for each sensor 106.

In embodiments, the cover 102 and/or the substrate 104 include recesses 112. The recesses 112 may be designed to correspond to the sensors 106 and/or the interconnects 108. One or both of the internal faces of the cover 102 and the substrate 104 can be fabricated or machined with the recesses 112 that align with the locations of the sensors 106 and wiring when the sensor module 100 is assembled. The recesses 112 may ensure that any components that have thickness (e.g., the sensors 106 or the interconnects 108) do not prevent the cover 102 from coming into contact with the substrate 104 during bonding. The recesses 112 may be formed by etching, milling, laser ablation, or any suitable material removal process. The depth or size of the recesses 112 may be set according to the profile of the sensor 106 or interconnect 108 that the particular recess 112 houses.

Various integration techniques for sensors 106 and interconnects 108 may be used in the sensor module 100. For example, the sensors 106 and interconnects 108 may be directly integrated into the substrate 104 (e.g., using thin-film deposition, lithography, and etching or printing processes), providing a high degree of miniaturization and robustness. Alternatively, sensors 106 may be discrete components that are bonded into the recesses 112. Use of the recesses 112 may be advantageous if certain sensors 106 are not easily fabricated on the substrate 104 or cover 102 but are available as small packaged units (e.g., a small piezoelectric accelerometer chip attached to monitor vibration).

In embodiments, the sensor module 100 includes a cable 114. The cable 114 is an elongated, flexible electrical connector attached at the edge of the cover 102 and the substrate 104. The cable 114 may be coupled to the data acquisition subsystem 118 and to the interconnects 108 at the convergence point 110. Therefore, the cable 114 may provide a physical link between the internal wiring of the sensor module 100 and external equipment or electronics.

The cable 114 may carry power and signals to the sensor module 100 from external instruments. Additionally, the cable 114 may carry sensor data out of the sensor module 100. The cable 114 is typically thin and bendable (e.g., a flex circuit or ribbon cable), which may allow it to exit the narrow gap between the cover 102 and substrate 104 without significantly disturbing the module's planarity or introducing a large gap at the bond interface. The cable 114 may be formed as any of a polyimide flexible circuit, discrete wires, metal printed on silicone, conductive traces printed on metal foil, or conductive traces printed on ceramic.

In embodiments, the sensor module 100 includes a cavity 116 to receive the cable 114. The cavity 116 may be positioned where the cable 114 exits the sensor module 100. The cavity 116 may be sized to allow the cable 114 to fit partially or fully within the edge profile of the sensor module 100. For example, if the cable 114 is a flex circuit of a certain thickness, a corresponding cavity 116 can be cut into the side of the substrate 104 so that when the cable 114 is laid into the cavity 116, the outer surface of the cable 114 is flush with the cylindrical edge of the substrate 104. By way of another example, the cover 102 may have a small cut-out to make room for the cable 114. By way of another example, both the cover 102 and substrate 104 include matching semi-circular notches at one location along their perimeter. When the cover 102 and substrate 104 are aligned during bonding, these notches may be aligned to form the cavity 116. By incorporating the cavity 116, the cable 114 may exit from the interior of the sensor module 100 without causing a separation that might compromise the flatness or the strength of the sensor module 100. The cavity 116 may also provide strain relief and alignment for the cable 114, helping to hold it securely and prevent it from tearing away from the sensor module 100 if pulled or bent during handling.

In embodiments, the sensor module 100 includes a data acquisition subsystem 118. The data acquisition subsystem 118 may be designed to interface with the sensors 106, collect their outputs, and facilitate communication of sensor data to external devices.

In embodiments, the data acquisition subsystem 118 may be a separate external unit (e.g., a bench-top data acquisition system or custom electronics box) that connects to the sensor module 100 via the cable 114 or wirelessly. Additionally, the data acquisition subsystem 118 may be integrated partially or entirely into the sensor module 100 itself. For example, the sensor module 100 may incorporate on-board electronics that are mounted or integrated on the cable 114. By integrating the data acquisition subsystem 118 functions with the cable 114, the sensor module 100 may operate in a self-contained manner without continuous wired connections to external instruments. This on-board data acquisition subsystem 118 may be communicatively coupled to the plurality of sensors 106 via the interconnects 108 at the convergence point 110, receiving data from each sensor 106.

FIG. 1D illustrates a block diagram of a data acquisition subsystem 118 of the sensor module 100, in accordance with one or more embodiments of the present disclosure.

In embodiments, the data acquisition subsystem 118 includes a battery 120. The battery 120 may be an on-board power source that provides electrical energy to the sensors 106 and the other electronic components of the sensor module 100, thereby enabling standalone operation. The battery 120 can be a rechargeable battery (e.g., a lithium-ion or lithium-polymer cell). As part of the data acquisition subsystem 118, the battery 120 may be mounted on the cable 114.

In embodiments, the data acquisition subsystem 118 includes one or more transmitters 122. The transmitter 122 may be used to send data (e.g., the sensor data or processed results) from the sensor module 100 to external receivers. The transmitter 122 may be a wireless communication module. The transmitter 122 may be mounted on the cable 114. This wireless transmission capability of the transmitter 122 may free the sensor module 100 from needing a physical data cable during use, thereby simplifying installation and removing the risk of wired connections interfering with tool operation (or being damaged by the tool).

In embodiments, the data acquisition subsystem 118 includes one or more receivers 124. The receiver 124 may allow the sensor module 100 to accept incoming wireless signals or commands from external devices. For instance, the sensor module 100 might need to receive a remote start command, configuration updates, or synchronization signals from a base station or control computer. The receiver 124 can be implemented independently as part of the data acquisition subsystem 118 or incorporated as part of the transmitter 122 (e.g., to form a transceiver). The receiver 124 may be mounted on the cable 114.

In embodiments, the data acquisition subsystem 118 includes a controller 126 communicatively coupled to the sensors 106, the controller including one or more processors 128 programmed to execute a set of program instructions stored in memory 130.

In embodiments, when executed, the program instructions cause the processors 128 to receive the sensor data from the sensors 106. The received sensor data may be temporarily stored in memory 130 for further processing or transmission. The timing and sequence of data acquisition may be controlled by the program logic, which may support continuous sampling, triggered acquisition, or periodic polling modes.

In embodiments, when executed, the program instructions cause the processors 128 to process the sensor data. Processing may include applying calibration coefficients, filtering noise, averaging multiple samples, or performing mathematical transformations to convert raw signals into meaningful physical quantities such as temperature, pressure, or vibration. The processors 128 may also perform threshold detection, event flagging, or statistical analysis to identify anomalies or trends in the measured data. This local processing may reduce the volume of data transmitted and enable real-time decision-making or alerts.

In embodiments, when executed, the program instructions cause the processors 128 to cause the transmitters 122 to transmit data (e.g., the sensor data). The transmission of the data may occur continuously, periodically, or in response to specific events or external commands. The transmitter 122 may send data to a nearby receiver, such as a base station, a tool-integrated antenna, or a remote monitoring system, enabling real-time observation or logging of process conditions.

In embodiments, when executed, the program instructions cause the processors 128 to receive data from the receivers 124 from an exterior source. This incoming data may include configuration parameters, synchronization signals, firmware updates, or control commands. Upon reception, the processors 128 may decode the data and adjust the behavior of the sensor module 100 accordingly (e.g., by changing sampling rates, enabling specific sensors 106, disabling specific sensors 106, or initiating a new measurement cycle). This bidirectional communication capability may enhance the flexibility and integration of the sensor module 100 within automated process control systems.

It is noted that the design of the sensor module 100 may take into account process compatibility and the environmental demands of semiconductor manufacturing. All materials (e.g., cover 102, substrate 104, any adhesive, and the cable 114) may be selected to withstand the high temperatures, vacuum conditions, and/or reactive chemicals of the target processes.

For example, for high-temperature use, the cover 102 and substrate 104 may be made of materials like silicon or glass (which remain stable at elevated temperatures) and bonded using methods such as direct bonding or anodic bonding that do not degrade under heat. By way of another example, the sensors 106 may be selected or designed for high-temperature operation (for example, using high-temperature strain gauges or thermocouples).

Additionally, the sensor module 100 may maintain a monolithic flat profile. The cover 102 and substrate 104 encase the sensors and interconnects with no external protrusions, so the sensor module 100 may be handled like a standard wafer. This flatness under compression may be critical for processes such as wafer bonding or chemical-mechanical polishing, where a uniform, planar surface is necessary to avoid process non-uniformities or damage.

The sensor module 100 may have the same general shape and dimensions as a standard wafer or substrate used in fabrication. However, because the cable 114 extends from the edge of the sensor module 100, special handling of the sensor module 100 may be needed during automated pick-and-place operations. To prevent the cable 114 from getting tangled, bent, or damaged when the sensor module 100 is moved by a robot, the orientation of the sensor module 100 may be controlled.

For example, the cable 114 may be aligned with the wafer's fiducial (e.g., a notch). Most automated handling systems grip wafers at fixed positions relative to a wafer's notch. Therefore, placing the cable 114 at the notch location (or 180° opposite) may make the position of the cable 114 predictable for the handler. Additionally, this orientation may help ensure the robot arm or cassette slot does not interfere with the cable.

By way of another example, a custom guide or clip may be used to temporarily secure the cable 114 against the edge of the sensor module 100 during transfer, releasing it once the sensor module 100 is in place inside the processing tool. By way of another example, an operator may manually position the cable 114 in a safe orientation on the robot if full automation is not feasible. These handling strategies may address one of the primary challenges of cabled sensor wafers by keeping the cable 114 from obstructing or snagging on equipment.

Alignment of the sensor module 100 within processing tools may be another consideration for the position of the cable 114. If the cable 114 is located at the notch, the cable 114 may interfere with an optical alignment sensor or a mechanical alignment pin expecting an open notch. Therefore, the cable 114 may be positioned near, but not exactly at, the notch (or the sensor module 100 may use an alternative alignment mark) to balance easy handling with proper tool alignment and sealing.

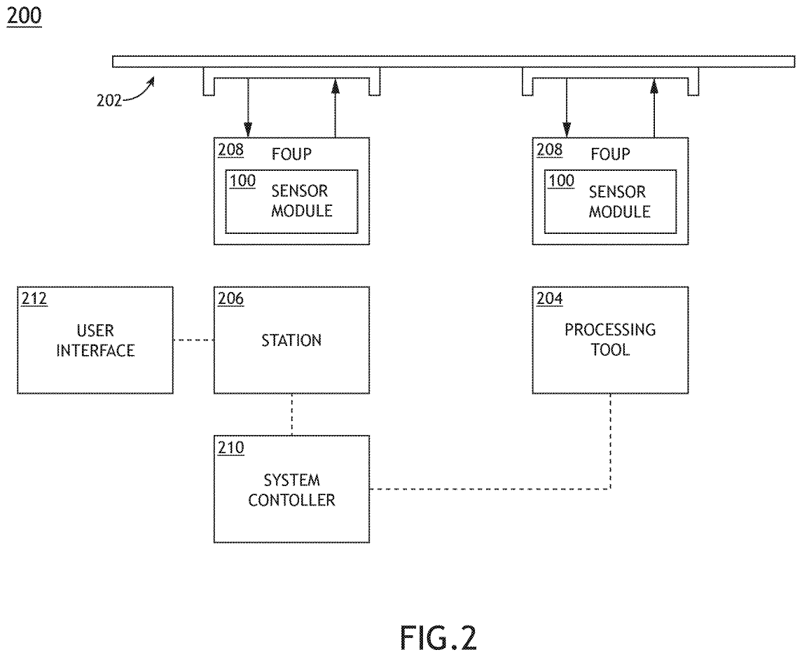

FIG. 2 depicts a block diagram of a system 200, in accordance with one or more embodiments of the present disclosure. The system 200 may be a substrate processing system. The system 200 may include the sensor module 100, an automatic material handling system 202 (AMHS), a processing tool 204, a station 206, front opening unified pods 208 (FOUP), a system controller 210, and/or a user interface 212.

The front opening unified pods 208 may be automation ready FOUPs that can communicate with a device manufacturer's fab automation system. Additionally, the front opening unified pods 208 may be designed such that they download sensor data from the sensor module 100 via an electronic system. The sensor data may then be transferred from the front opening unified pods 208 to the station 206. Subsequently, the station may transfer the sensor data to a fab automation system.

The front opening unified pods 208 may include one or more of the sensor modules 100. The front opening unified pods 208 may be designed to receive and secure the sensor modules 100. The sensor module 100 may be housed within the front opening unified pods 208. The front opening unified pods 208 may include a substrate carrier which may be integrated with the system 200. The front opening unified pods 208 may provide an environment for storing and transporting the sensor module 100.

The front opening unified pods 208 may be designed to exchange data with the data acquisition subsystem 118. For example, the front opening unified pods 208 may be designed to receive the sensor data from the data acquisition subsystem 118. The controller 126 of the sensor module 100 may be communicatively coupled to the front opening unified pods 208 by wireless communication. For instance, the front opening unified pods 208 may include communication circuitry (not depicted). The communication circuitry may include, but is not limited to, one or more communication antennas (e.g., a communication coil). The communication circuitry may be designed to establish a communication link between the controller 126 and the front opening unified pods 208. The front opening unified pods 208 may include a FOUP interface (not depicted). The FOUP interface may be the interface by which the front opening unified pods 208 may be designed to receive recipes, mission start commands, relay back mission data, and the like.

The automatic material handling system 202 may position the front opening unified pods 208 in three dimensions. The automatic material handling system 202 may include an overhead track (OHT) system. The space occupied by the automatic material handling system 202 may be above the normal floor working level. The automatic material handling system 202 may pick the front opening unified pods 208 from the station 206 and transport the front opening unified pods 208 to the processing tool 204. Similarly, the automatic material handling system 202 may pick the front opening unified pods 208 from the processing tool 204 and transport the front opening unified pods 208 to the station 206.

The station 206 may be an automation station. The station 206 may be an automated material handling system (AMHS) compatible station. The station 206 may host the front opening unified pods 208. The station 206 may be designed to receive the front opening unified pods 208. The station 206 may communicate with the front opening unified pods 208. The station 206 may also recharge the front opening unified pods 208. The station 206 may communicate with the system controller 210.

The processing tool 204 may be designed to receive the sensor module 100. The automatic material handling system 202 may also be designed to remove the sensor module 100 from the front opening unified pods 208 and place the sensor module 100 within a pathway of the illumination.

The sensor module 100 may include a thickness that is sufficiently small to meet a specification of a processing chamber (e.g., epitaxy chamber, plasma etch chamber) of the processing tool 204. For example, the sensor module 100 may include a maximum thickness of 10 mm or less to fit into various process chambers. For instance, the maximum thickness may be 50 mm or less, 10 mm or less, 6 mm or less, 5 mm or less, 2 mm or less, or smaller.

The processing tool 204 may be designed to generate illumination. The processing tool 204 may be designed to generate the illumination using a plasma or the like. For example, the processing tool 204 may include an EUV lithography tool or the like. The processing tool 204 may generate the illumination in an image plane on the sensor module 100.

The sensor module 100 may be designed to monitor process conditions within a process chamber of the processing tool 204. The sensor module 100 may provide a metrology platform for calibrating and monitoring the illumination in the processing tool 204. The processing tool 204 may use the sensor data for optimal semiconductor process performance.

The sensor module 100 may be subject to extreme conditions within the processing tool 204. The extreme conditions may include aggressive chemistry, high and low temperature extremes, and/or extreme pressures. The extreme conditions may be found in etch environments or other wafer processing environments. The material of the sensor module 100 may cause negligible contamination in the processing tool 204. The cover 102 and/or the substrate 104 may shield the sensor 106 and interconnects 108 from extreme conditions (e.g., high RF, high heat flux, high electromagnetic radiation) within process chambers of the processing tool 204. Thus, the sensor module 100 may include the enclosure assembly 103, which may survive the extreme environments.

The system controller 210 and the sensor module 100 may control an interface through the front opening unified pods 208 and the station 206 and/or an interface through the processing tool 204. The system controller 210 may process data from the sensor module 100 for statistical processing control (SPC). The system 200 may have the ability to automatically add data collected from the sensor module 100 to a database within the system controller 210.

A mission may be a data collection session of the sensor module 100 and the following download of data from the sensor module 100. The mission may be initiated by the system controller 210 for the purpose of ascertaining the health of the processing tool 204. The mission may be communicated to the station 206 that hosts the front opening unified pods 208. The station 206 may communicate the mission to the front opening unified pods 208. The front opening unified pods 208 may then communicate the mission to the sensor module 100. The sensor module 100 may then execute the mission for determining the health of the processing tool 204.

The user interface 212 may be communicatively coupled to the station 206. The user interface 212 may include, but is not limited to, one or more desktops, laptops, tablets, and the like. The user interface 212 may include a display used to display data of the system to a user. The display of the user interface 212 may include any display known in the art. For example, the display may include, but is not limited to, a liquid crystal display (LCD), an organic light-emitting diode (OLED) based display, or a cathode ray tube (CRT) display. Those skilled in the art should recognize that any display device capable of integration with a user interface is suitable for implementation in the present disclosure. A user may input selections and/or instructions responsive to data displayed to the user via a user input device of the user interface 212.

Any of the various components of the system 200 may be designed to communicate using a selected communications protocol. For example, the selected communications protocol may include an industry standard communications protocol consistent with standards defined by the Semiconductor Equipment and Materials Institute (SEMI). These standards are referred to as SEMI Equipment Communications Standards (SECS) and Generic Equipment Model (GEM).

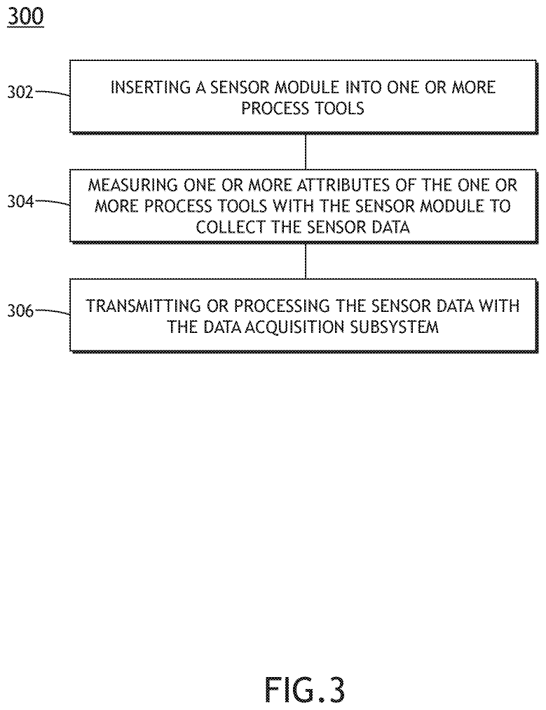

FIG. 3 illustrates a flow diagram of a method 300 for using the sensor module 100 in a system 200 for manufacturing semiconductors, in accordance with one or more embodiments of the present disclosure. The applicant notes that the embodiments and enabling technologies described previously herein in the context of the sensor module 100 and/or the system 200 should be interpreted to extend to the method 300. It is further noted, however, that the method 300 is not limited to the architecture of the sensor module 100 and/or the system 200.

In embodiments, the method 300 includes a step 302 of inserting a sensor module into one or more processing tools. The sensor module may be loaded into a semiconductor manufacturing tool using standard wafer handling equipment or manually, depending on the tool configuration. The sensor module may be placed on a process chuck or stage, replicating the position and orientation of a production wafer. The cable extending from the module may be routed or positioned to avoid interference with tool components, and the sensor module may be aligned using standard wafer fiducials or custom alignment features.

In embodiments, the method 300 includes a step 304 of measuring one or more attributes of the one or more processing tools with the sensor module to collect the sensor data. The attributes may include temperature, pressure, vibration, or other environmental or mechanical parameters relevant to the tool's operation. The sensors embedded within the sensor module may detect these conditions during tool operation, such as during bonding, heating, or plasma exposure. The data acquisition subsystem may collect signals from the sensors in real time, enabling accurate monitoring of tool performance under actual process conditions.

In embodiments, the method 300 includes a step 306 of transmitting or processing the sensor data with the data acquisition subsystem. The data acquisition subsystem may process the raw sensor signals to apply calibration, filtering, or statistical analysis. The processed data may then be transmitted to an external system via a wired connection through the cable or wirelessly using an integrated transmitter. Additionally, the data may be stored locally for later retrieval or transmitted without any processing occurring. This may enable real-time or post-process analysis of tool conditions, supporting diagnostics, calibration, and process optimization.

Referring again to the controller 126, additional aspects of the controller 126, the processors 128, and the memory 130 are described. In some embodiments, the controller 126 includes one or more processors 128. For example, the one or more processors 128 may be designed to execute a set of program instructions maintained in the memory 130, or a memory device.

The one or more processors 128 of a controller 126 may include any processor or processing element known in the art. For the purposes of the present disclosure, the term “processor” or “processing element” may be broadly defined to encompass any device having one or more processing or logic elements (e.g., one or more microprocessor devices, one or more application-specific integrated circuit (ASIC) devices, one or more field-programmable gate arrays (FPGAs), or one or more digital signal processors (DSPs)). In this sense, the one or more processors 128 may include any device designed to execute algorithms and/or instructions (e.g., program instructions stored in memory). In embodiments, the one or more processors 128 may be embodied as a desktop computer, mainframe computer system, workstation, image computer, parallel processor, networked computer, or any other computer system designed to execute a program designed to operate or operate in conjunction with the sensor module 100, as described throughout the present disclosure. Moreover, different subsystems of the sensor module 100 may include a processor or logic elements suitable for carrying out at least a portion of the steps described in the present disclosure. Therefore, the above description should not be interpreted as a limitation on the embodiments of the present disclosure, but merely as an illustration. Further, the steps described throughout the present disclosure may be carried out by a single controller or, alternatively, multiple controllers. Additionally, the controller 126 may include one or more controllers housed in a common housing or within multiple housings. In this way, any controller or combination of controllers may be separately packaged as a module suitable for integration into the sensor module 100.

The memory 130 may include any storage medium known in the art suitable for storing program instructions executable by the associated one or more processors 128. For example, the memory 130 may include a non-transitory memory medium. By way of another example, the memory 130 may include, but is not limited to, a read-only memory (ROM), a random-access memory (RAM), a magnetic or optical memory device (e.g., disk), a magnetic tape, a solid-state drive, and the like. It is further noted that the memory 130 may be housed in a common controller housing with the one or more processors 128. In some embodiments, the memory 130 may be located remotely with respect to the physical location of the one or more processors 128 and the controller 126. For instance, the one or more processors 128 of the controller 126 may access a remote memory (e.g., server), accessible through a network (e.g., internet, intranet, and the like).

One skilled in the art will recognize that the herein-described components, operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for the sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components. Likewise, any two components so associated can also be viewed as being “connected,” or “coupled,” to each other to achieve the desired functionality, and any two components capable of being so associated can also be viewed as being “couplable” to each other to achieve the desired functionality. Specific examples of couplable components include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A sensor module comprising:
a cover;
a substrate located opposite the cover, wherein the substrate and the cover are bonded to each other;
a plurality of sensors positioned between the cover and the substrate, wherein the plurality of sensors is coupled to each other by a plurality of interconnects;
a data acquisition subsystem communicatively coupled to the plurality of sensors, wherein the data acquisition subsystem is designed to receive sensor data from the plurality of sensors; and
a cable at an edge of the cover and the substrate, wherein the cable is coupled to the data acquisition subsystem and the plurality of interconnects at a convergence point of the plurality of interconnects.

2. The sensor module of claim 1, further comprising:
a plurality of recesses corresponding to the plurality of sensors, wherein the plurality of recesses is located in either the cover or the substrate, wherein the plurality of sensors and the plurality of interconnects are positioned in the plurality of recesses.

3. The sensor module of claim 1, wherein the plurality of sensors and the plurality of interconnects are integrated directly into the substrate.

4. The sensor module of claim 1, wherein the data acquisition subsystem comprises:
a controller communicatively coupled to the plurality of sensors, the controller including one or more processors programmed to execute a set of program instructions stored in memory, which when executed, cause the one or more processors to:
receive the sensor data from the plurality of sensors; and
process the sensor data.

5. The sensor module of claim 1, wherein the data acquisition subsystem comprises:
a battery to power the data acquisition subsystem.

6. The sensor module of claim 1, wherein the data acquisition subsystem comprises:
one or more transmitters to transmit the sensor data received by the data acquisition subsystem.

7. The sensor module of claim 1, wherein the data acquisition subsystem is directly integrated into the cable.

8. The sensor module of claim 1, wherein the plurality of sensors is designed to measure at least one of compressive force, temperature, or vibration.

9. The sensor module of claim 1, wherein the substrate is bonded to the cover by one of adhesive bonding, direct bonding, or anodic bonding.

10. The sensor module of claim 1, wherein the cable is formed as one of a polyimide flexible circuit, discrete wires, metal printed on silicone, conductive traces printed on metal foil, or conductive traces printed on ceramic.

11. The sensor module of claim 1, wherein the substrate and the cover are wafers.

12. The sensor module of claim 1, wherein the substrate and the cover are panels.

13. A system comprising:
one or more processing tools; and
a sensor module designed to measure one or more attributes of the one or more processing tools, the sensor module comprising:
a cover;
a substrate located opposite the cover, wherein the substrate and the cover are bonded to each other;
a plurality of sensors positioned between the cover and the substrate, wherein the plurality of sensors is coupled to each other by a plurality of interconnects;
a data acquisition subsystem communicatively coupled to the plurality of sensors, wherein the data acquisition subsystem is designed to receive sensor data from the plurality of sensors; and
a cable at an edge of the cover and the substrate, wherein the cable is coupled to the data acquisition subsystem and the plurality of interconnects at a convergence point of the plurality of interconnects.

14. The system of claim 13, further comprising:
a plurality of recesses corresponding to the plurality of sensors, wherein the plurality of recesses is located in either the cover or the substrate, wherein the plurality of sensors and the plurality of interconnects are positioned in the plurality of recesses.

15. The system of claim 13, wherein the plurality of sensors and the plurality of interconnects are integrated directly into the substrate.

16. The system of claim 13, wherein the data acquisition subsystem comprises:
a controller communicatively coupled to the plurality of sensors, the controller including one or more processors programmed to execute a set of program instructions stored in memory, which when executed, cause the one or more processors to:
receive the sensor data from the plurality of sensors; and
process the sensor data.

17. The system of claim 13, wherein the data acquisition subsystem comprises:
a battery to power the data acquisition subsystem.

18. The system of claim 13, wherein the data acquisition subsystem comprises:
one or more transmitters to transmit the sensor data received by the data acquisition subsystem.

19. The system of claim 13, wherein the data acquisition subsystem is directly integrated into the cable.

20. The system of claim 13, wherein the plurality of sensors is designed to measure at least one of compressive force, temperature, or vibration.

21. The system of claim 13, wherein the substrate is bonded to the cover by one of adhesive bonding, direct bonding, or anodic bonding.

22. The system of claim 13, wherein the cable is formed as one of a polyimide flexible circuit, discrete wires, metal printed on silicone, conductive traces printed on metal foil, or conductive traces printed on ceramic.

23. The system of claim 13, wherein the substrate and the cover are wafers.

24. The system of claim 13, wherein the substrate and the cover are panels.

25. The system of claim 13, further comprising:
a front opening unified pod configured to receive the sensor module.

26. The system of claim 25, wherein the front opening unified pod contains an electronic system to download sensor data from the sensor module.

27. The system of claim 26, wherein the sensor data is transferred from the front opening unified pod to a station, wherein the station transfers the sensor data to a fab automation system.

28. A method comprising:
inserting a sensor module into one or more processing tools, wherein the sensor module comprises:
a cover;
a substrate located opposite the cover, wherein the substrate and the cover are bonded to each other;
a plurality of sensors positioned between the cover and the substrate, wherein the plurality of sensors is coupled to each other by a plurality of interconnects;
a data acquisition subsystem communicatively coupled to the plurality of sensors, wherein the data acquisition subsystem is designed to receive sensor data from the plurality of sensors; and
a cable at an edge of the cover and the substrate, wherein the cable is coupled to the data acquisition subsystem and the plurality of interconnects at a convergence point of the plurality of interconnects;
measuring one or more attributes of the one or more processing tools with the sensor module to collect the sensor data; and
transmitting or processing the sensor data with the data acquisition subsystem.
